(19) United States
(12) Patent Application Publication
(10) Pub. No.: US 2025/0389767 A1
(43) Pub. Date: Dec. 25, 2025

(54) VOLTAGE DROP DETECTION IN A POWER GRID ON AN INTEGRATED CIRCUIT

(71) Applicant: INTERNATIONAL BUSINESS MACHINES CORPORATION, ARMONK, NY (US)

(72) Inventors: JOHN BORKENHAGEN, ROCHESTER, MN (US); JOSHUA M CHICA, ROCHESTER, MN (US); GRANT P. KESSELRING, ROCHESTER, MN (US); JAMES STROM, ROCHESTER, MN (US)

(21) Appl. No.: 18/753,616

(22) Filed: Jun. 25, 2024

(51) Int. Cl. G01R 31/28

(52) U.S. Cl. CPC G01R 31/2884

(57) ABSTRACT

An integrated circuit includes at least one on-chip power conductor network, also referred to as a power grid, configured to distribute electrical power to a plurality of electrical components on the integrated circuit. Voltage drop detection circuitry selects each of a plurality of tap points from the on-chip power conductor network and in response to a plurality of selected tap points, provides data representing a frequency corresponding to a voltage level of each of the selected plurality of tap points. The data is used in some implementations to detect a short circuit in the power grid and in other implementations is used to generate a voltage drop map that identifies the locations in the power grid where power drops are beyond a desired threshold.

### BACKGROUND

The present disclosure relates to methods and apparatus for detecting voltage drops in integrated circuit power grids.

In today's integrated circuits such as very large scale integration (VLSI) microprocessor designs, digital processors such as central processing units (CPUs), graphics processing units (GPUs) and other types of processors contain many different on-chip power conductor networks, also referred to as power grids, configured to distribute electrical power to a plurality of electrical circuits on the integrated circuit to support several voltage domains. These power grids are made of wire which carry power to the circuits within the processors. The distance from a power grid tap-point to a circuit can vary greatly. As a result, there can be a significant amount of voltage (IR) drop seen “at circuit” due to the length of wire from power grid to a circuit.

### SUMMARY

According to embodiments of the present disclosure, various methods, circuits, apparatus and products for detecting voltage drops in integrated circuit power grids are described herein. In some aspects, an integrated circuit includes at least one on-chip power conductor network, also referred to as a power grid, configured to distribute electrical power to a plurality of electrical components on the integrated circuit. Voltage drop detection circuitry selects each of a plurality of tap points from the on-chip power conductor network and in response to a plurality of selected tap points, provides data representing a frequency corresponding to the selected plurality of tap points. The data is used in some implementations to detect a short circuit in the power grid and in other implementations is used to generate a voltage drop map that identifies the locations in the power grid where power drops are beyond a desired threshold.

### BRIEF DESCRIPTION OF THE DRAWINGS

FIG. 1 sets forth an example integrated circuit according to aspects of the present disclosure.

FIG. 2 sets forth an example integrated circuit with voltage drop detection circuitry according to aspects of the present disclosure.

FIG. 3 sets forth a flowchart of an example process for detecting voltage drops in an on-chip power conductor network according to aspects of the present disclosure.

FIG. 4 sets forth a flowchart of an example process for detecting voltage drops in an on-chip power conductor network to facilitate voltage drop mapping according to aspects of the present disclosure.

FIG. 5 sets forth a flowchart of an example process for detecting voltage drops in an on-chip power conductor network to facilitate short circuit detection according to aspects of the present disclosure.

FIG. 6 sets forth another example integrated circuit with voltage drop detection circuitry according to aspects of the present disclosure.

FIG. 7 is a diagram illustrating an example of a pass gate circuit in voltage drop detection circuitry according to aspects of the present disclosure.

FIG. 8 is a diagram illustrating an example of level shifting for a ring oscillator according to aspects of the present disclosure.

FIG. 9A is a diagram illustrating an example of a splitter circuit for a level shifting circuit according to aspects of the present disclosure.

FIG. 9B is a diagram illustrating an example of a level shifting circuit for a ring oscillator according to aspects of the present disclosure.

### DETAILED DESCRIPTION

In some implementations, an on-chip circuit and method measures voltage (IR) drops within a power grid to create a voltage (IR) map of all or a portion of the power grid on an integrated circuit and/or to detect shorts in the power grid. In some implementations, for voltage drop mapping, a multiplexer circuit is coupled to tap points of the power grid and to reference voltages from a ring oscillator, such as a supply voltage to inverters of the ring oscillator and the ground voltage of the inverters from the ring oscillator. In some examples, the ring oscillator includes a plurality of passgates, each of the plurality of passgates are interposed between an inverter of the ring oscillator. In some implementations, control circuitry is operative to control the multiplexer circuit to provide a respective signal from each of a first output and a second output, the signals from each of the first and second outputs are coupled as an input to each of the pass gates. In one example, the output is a selected tap point signal that is a power supply reference voltage (VDD or VSS) that is coupled to the ring oscillator (VDD or VSS) and a second output is a selected tap point signal from the power grid.

In some implementations, an on-chip short circuit detection circuit detects one or more short circuits or locations that are becoming short circuits in the power grid. In one example, the short circuit detection circuit includes a multiplexer circuit, a ring oscillator that includes a plurality of passgates, each of the plurality of pass gates interposed between an inverter of the ring oscillator, and control circuitry that is operative to control the multiplexer circuit to provide as a first output, a selected power voltage tap point from the power grid, and to provide as a corresponding second output, a corresponding selected ground tap point from the power grid, each of the first and second outputs are coupled as an input to each of the passgates. The ring oscillator is used with passgates located between inverters and the passgates are driven by the voltage levels at various tap points of the power grid to create a frequency. This frequency is compared against a known frequency of a nominal circuit to determine if there is a short in the system. In some implementations, the short detection mode is used in a low power mode of the chip and the circuit measures and compares each tap point against the next tap point and keeps the lowest frequency to locate a short. The lowest overall frequency is determined to be closest to the short. This can be useful to isolate shorted locations within a large power grid.

In some implementations the on-chip circuit is located on-chip with one or more processors and is switched between modes. In a voltage drop map mode, the circuit is run to map power grid voltage drops over the chip. In a short circuit detection mode the circuit is run to detect the location of a short circuit within the chip. The short detection mode is a low power operation that measures and compares each tap point pair against the next tap point pair and keeps the lowest frequency wherein the lowest overall frequency is closest to the short.

In some implementations, for example, the short detection mode is a low power mode that measures and compares each tap point against the next and keeps the lowest frequency wherein the lowest overall frequency is closest to the short. In some implementations, a ring oscillator and passgates located between inverters of the ring oscillator are driven by various tap points of the power grid to create a frequency indicating a voltage drop at a tap point. In some implementations, data representing the frequency at each tap point, is used as a map point and stored on-chip or provided off chip. Chip designers can use the IR map to identify problems and change circuit designs if desired. In some implementations, the IR map is used during runtime of one or more applications executing on the processor. For example, in some implementations, during runtime each tap point (e.g., tap point pair) is measured and compared to a minimum threshold. A multiplexer output that is connected to each tap point is swept to measure each tap point every x seconds. When any tap point is less than the minimum threshold then a “call home” notification is sent indicating that a tap point is near failure. The CPU could then be swapped out or the circuit could be powered off by a field technician.

In some implementations, the disclosed system serves as a built voltage (IR) drop mapping system for one or more power grids in an integrated circuit. In one example, the IR drop mapping system uses a ring oscillator and pass gates that are driven by various tap points of a power grid to create a frequency. If desired the same circuit is controlled to also or instead detect short circuits. For short circuit detection the frequency, in some implementations, is compared against a known frequency of a nominal circuit to determine if there is a short in the system. Locating short circuit locations or locations that are approaching a short circuit (also referred to as soft shorts) is useful in manufacturing integrated circuit screening operations and/or failure analysis of the integrated circuit before or after a failure has occurred.

For short circuit detection, the disclosed ring oscillator configuration is superior to a comparator short circuit detection system as it allows for greater granularity to flag shorts before they become severe. Lastly, a ring voltage controlled oscillator (VCO) can measure a wide range of voltages without the need for multiple reference voltages. Whereas a comparator based solution would need several reference voltages based on the desired voltage range.

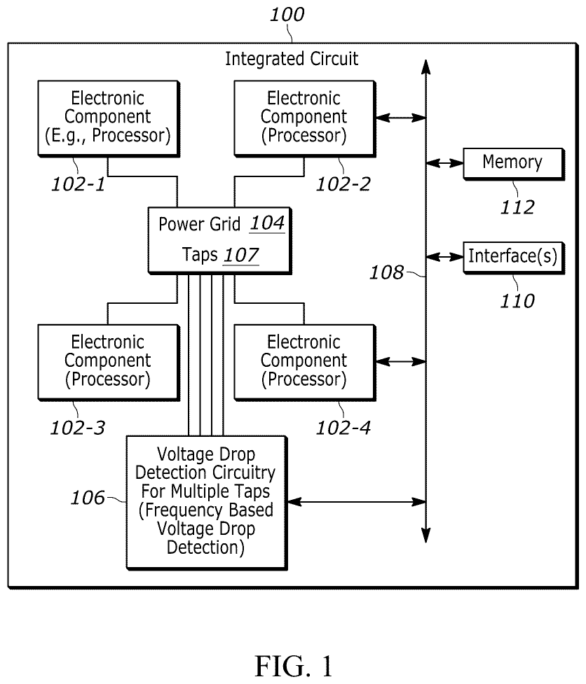

With reference now to FIG. 1, an example integrated circuit 100, which may also be referred to in some implementations as an integrated circuit chip, includes electronic components 102-1, 102-2, 102-3 and 102-4 that are powered by power grid 104. The power grid 104 is an on-chip power conductor network that distributes electrical power to the electrical components 102-1, 102-2, 102-3 and 102-4 on the integrated circuit. The electronic components in this example include one or more processors such as central processing units (CPUs), digital signal processing (DSP) chips, graphic processing units (GPUs), system-on-a-chip (SOC), three-dimensional integrated circuits (3D-IC), application-specific integrated circuits (ASICs), or any suitable electronic circuit. The integrated circuit 100 includes voltage drop detection circuitry 106 that is coupled to tap points 107 of the power grid. The voltage drop detection circuitry 106 provides a power grid frequency based voltage drop detection circuit for use in mapping voltage drops in the power grid and/or to detect short circuits in the power grid.

The integrated circuit 100 also includes memory 112, operatively coupled through one or more bus structures 108. The memory may include volatile memory, random access memory (RAM), nonvolatile random access memory (NVRAM), read-only memory (ROM), programmable read-only memory (PROM), erasable programmable read-only memory (EPROM) or any suitable memory. In some implementations the integrated circuit 100 includes one or more interfaces 110 such as interfaces that couple to a data analysis system to interpret the voltage map data generated by the voltage drop detection circuitry and/or the short circuit data generated on chip. The interface 110 in some implementations include interfaces to solid-state drives (SSD), and the integrated circuit 100 may be part of a hybrid cloud infrastructure or other system.

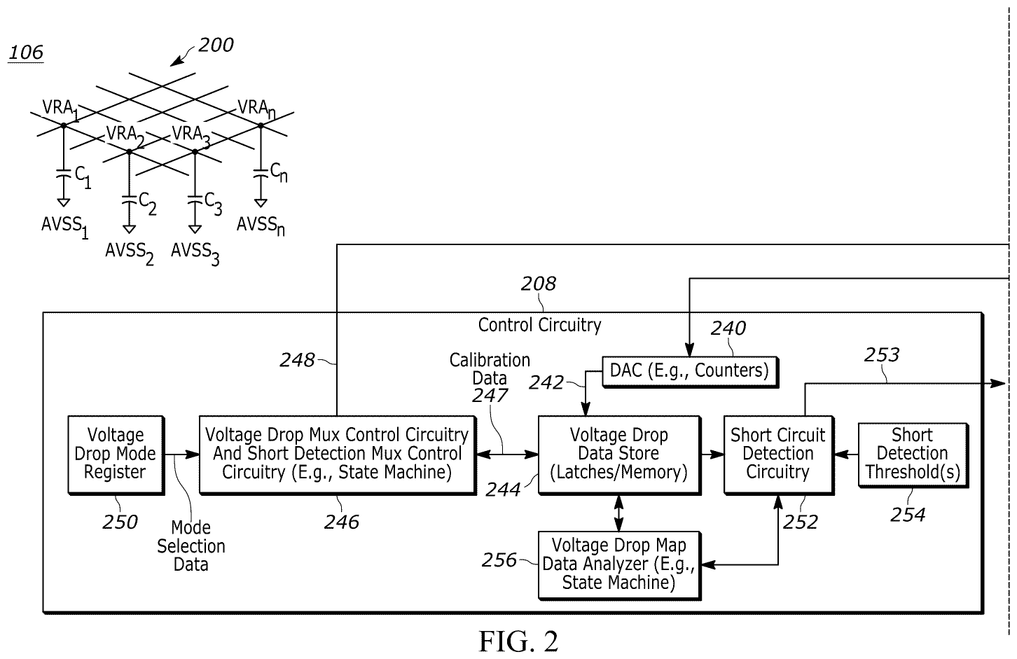

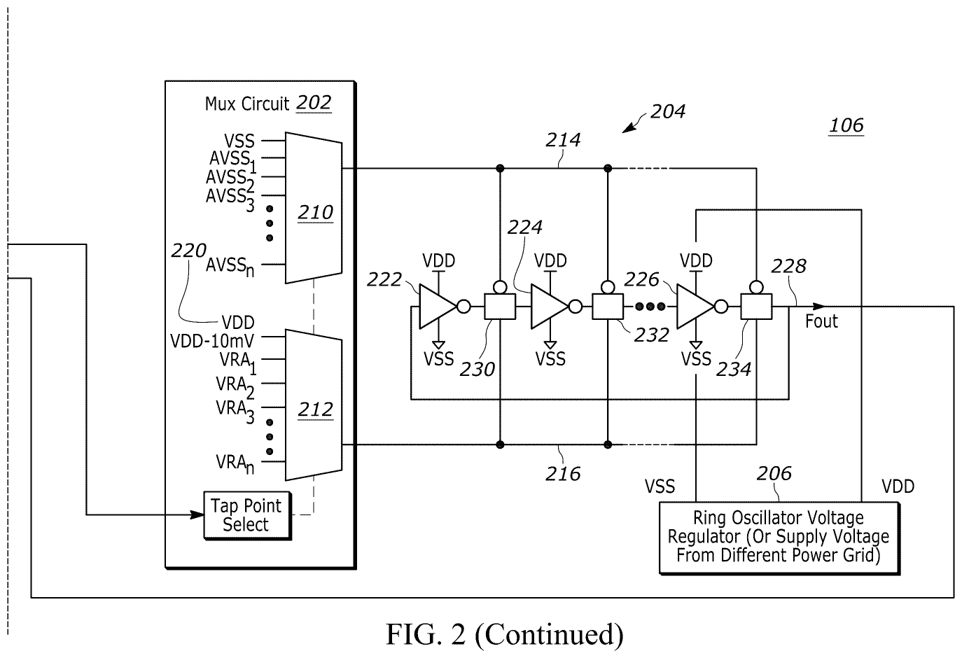

FIG. 2 illustrates an example of a voltage drop detection circuit 106 connected to a standard on-chip power grid 200 with decoupling capacitors C₁, C₂₁, C_{3 1}and C₄₁between corresponding grid power (VRA) tap points (VRA₁₋₄₁) and grid ground (AVSS) tap points AVSS₁₋₄₁. In this example the voltage drop detection circuit 106 operates in two different modes. One mode provides measurements and mapping of voltage drops in the power grid and another mode measures voltage drops in the power grid to detect short circuits or provide soft short detection. However, it will be recognized that each mode of operation can be configured as its own standalone circuit if desired. In some implementations, when in short circuit detection mode, the circuit compares short measurements over time and when the measurements show an increasing soft short level beyond a threshold the circuit sends a notification to an operating system or other system on the integrated circuit to notify the OS of a potential error.

In one example, the voltage drop detection circuit 106 includes a multiplexer circuit 202, a ring oscillator 204, a ring oscillator voltage supply 206 and control circuitry 208. In this example, the multiplexer circuit 202 is configured to facilitate both modes of operation. The multiplexer circuit includes a ground multiplexer 210 and a power multiplexer 212. The ground multiplexer 210 has a ring oscillator ground reference tap point input (VSS) and a plurality of tap point inputs that are coupled to the ground tap points of the power grid (AVSS₁-AVSSₙ). The ground reference tap point input is connected to the ground reference VSS of the ring oscillator. The ground multiplexer 210 has an output 214 that provides a signal from a selected tap point and couples to the ring oscillator 204. The ground multiplexer 210 outputs the selected ground tap point input as the output 214. The power multiplexer 212 has a ring oscillator power reference tap point input (VDD) and a plurality of tap point inputs that are coupled to the power tap points of the power grid (VRA₁-VRAₙ). The power reference tap point input is connected to the power voltage VDD of the ring oscillator. The power multiplexer 212 has an output 216 that provides a signal from the selected tap point and the output 216t also couples to the ring oscillator 204. The power multiplexer 212 outputs the selected power tap point input as the output 216. For calibration purposes, the power multiplexer also has a calibration reference input 220 as further described below.

The multiplexer circuit 202 provides selected inputs on outputs 214 and 216, each output is a different selected tap point from the plurality of input tap points of the ground and power multiplexers 210 and 212. The ring oscillator 204 includes an odd number of serially coupled inverters 222, 224 and 226 and an output from a last of the odd number of serially coupled inverters that is coupled to an input of a first inverter 222 of the serially coupled inverters. Three inverters are shown, however any suitable odd number may be employed. The ring oscillator 204 includes a passgate 230, 232 and 234 interposed between each respective serially coupled inverter. Each passgate 230, 232 and 234 have an input that receives each of the outputs 214 and 216 from the multiplexer circuit. The ring oscillator voltage supply 206 provides a different power and ground voltage to the ring oscillator than the power and ground from the power grid being measured. In one example a voltage regulator provides the power VDD and ground VSS to the inverters and other circuitry of the ring oscillator. In other examples, other power grids from the integrated circuit are used to supply the power and ground references to the ring oscillator. The ring oscillator is a voltage controlled oscillator (VCO) that outputs a frequency Four on output 228 corresponding to the selected tap points that are provided as outputs 214 and 216 to the passgates from the multiplexers 210 and 212. As such, the outputs of each multiplexer are fed to the passgates in the ring oscillator.

In this example, the voltage drop detection circuitry 106 selects each of a plurality of the tap points from the multiplexer which has inputs coupled to the on-chip power conductor network. In response to a plurality of selected tap points, the voltage drop detection circuitry 106 provides data representing a frequency corresponding to the voltage level corresponding to the selected plurality of tap points. For example, as further set forth below, the tap points include one or more tap points from the power grid that are used as input signals to passgates of the ring oscillator to generate a frequency representing a voltage level with respect to selected tap points. In some implementations, the data representing the frequency is stored in the memory 112 for use by on-chip voltage mapping circuitry and/or short detection circuitry or is provided off-ship for processing.

In this example, control circuitry 208 includes a digital to analog converter (DAC) 240 that converts the output frequency from the ring oscillator to digital data 242 which in some examples is one or more digital words that are stored in memory 244. The control circuitry 208 includes voltage drop mux control circuitry and short detection mux control circuitry 246, such as one or more state machines, that provides mux control information 248 to the multiplexers 210 and 212 to select respective tap point inputs to be output as output 214 and 216 respectively. In this example, a voltage drop mode register 250 includes data indicating which mode the voltage drop mux control circuitry and short detection mux control circuitry 246 is to operate in. The voltage drop mode register can be set by a processor executing an operating system, can be set with fuses, or can be set in any suitable manner. The control circuitry 208 in this example includes short circuit detection circuitry 252 that uses short detection threshold data 254 that is stored in memory such as one or more registers to detect whether there is a short in the power grid as further described below.

In this example the control circuitry 208 also includes a voltage drop map data analyzer 256 that is one or more state machines, that in the voltage mapping mode, compares the data 242 representing the frequency to one or more thresholds to determine if a particular tap point has a voltage that is higher or lower than a desired threshold and if so stores the location and or value to represent a hotspot in a power grid for use for example by chip designers to change circuit designs if desired. In some implementations, the data 242 is provided off-chip to a data analysis system. For example, the short circuit detection circuitry 252 and voltage drop map data analyzer operations are performed off chip if desired.

As shown, power voltage tap points VRA₁, VRA₂, . . . , VRAₙ and corresponding ground tap points AVSS₁, AVSS₂, . . . , AVSSₙ denote the various tap point pairs to measure local voltage (IR) drop for short circuit detection. The VRA and AVSS tap points are routed to the analog multiplexing circuit 202 that is controlled by the control circuitry 246 to select each tap point and the ring oscillator 204 measures the voltage potential at each tap point pair and outputs a frequency corresponding to the selected tap points from the multiplexers. The DAC 240 in some implementations is a state machine and/or counter attached to Fₒᵤₜ to measure and record the ring oscillator frequency on-chip. In some implementations, the control circuitry 208 is a programmed microcontroller, however any suitable structure may be employed.

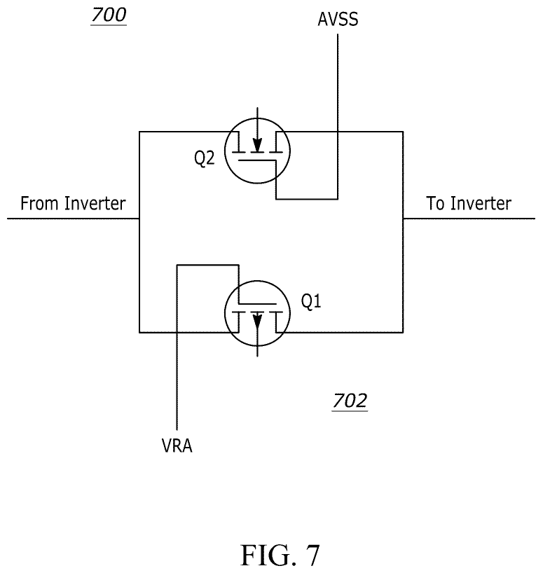

The ring oscillator includes an odd number of alternating inverter, passgate, inverter, passgate stages. The odd number of elements ensures a continuous oscillation. The number of stages and passgate voltage determines the frequency of oscillation. A higher voltage on the positive passgate terminal results in a faster frequency, and a lower voltage results in a slower frequency. The opposite is true for the negative terminal. A lower voltage results in a faster frequency, and a higher voltage results in a slower frequency. Connecting the VRA/AVSS tap points from the multiplexers to the FET gate terminal (see FIG. 7) of the passgates ensures no current consumption and no alteration to the power grid. In addition, as shown the inverters 222, 224 and 226 are powered by a separate “reference” power and ground (VDD,VSS) from the reference power supply 206 to reduce unwanted frequency modulation and ensure operation in the event the power supply being measured (VRA) is severely shorted.

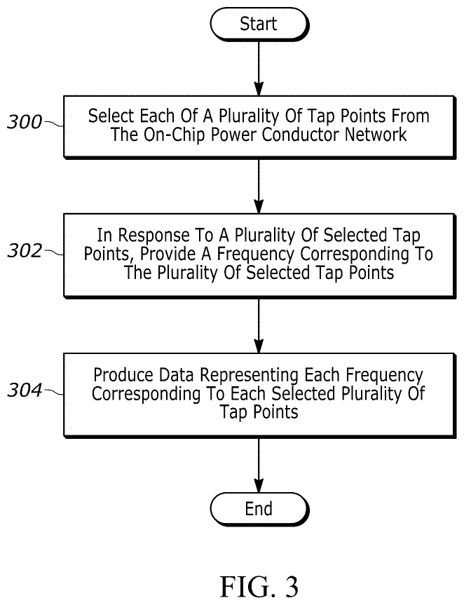

FIG. 3 sets forth an example method for detecting voltage drops in a power grid on an integrated circuit. In this example, the method is carried out by the voltage drop detection circuitry. As shown in block 300 the method includes selecting each of a plurality of tap points from the on-chip power conductor network. For example, in some implementations this includes the control circuitry sending the control information 248 to the multiplexer circuit 202 to output selected tap point inputs to provide to the passgates of the ring oscillator. As shown in block 302 the method includes, in response to a plurality of selected tap points, providing a frequency Fout corresponding to the plurality of selected tap points. In some implementations, this is done by the ring oscillator converting the voltages on the inputs of the passgates to a corresponding frequency. As shown in block 304, the method includes producing data representing each frequency corresponding to each selected plurality of tap points. In some implementations, this is done by the DAC 240 that performs an analog to digital conversion on the frequency output by the ring oscillator.

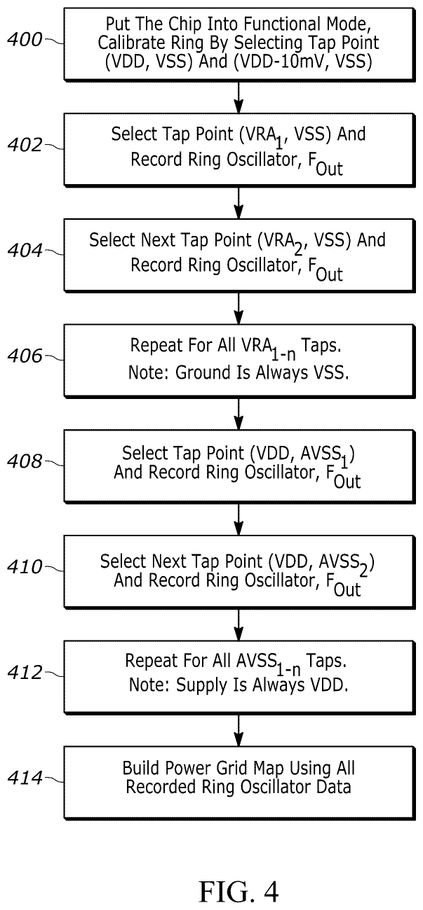

FIG. 4 sets forth an example method for measuring and mapping voltage drops across a power grid when the voltage drop detection circuitry is set in the voltage drop mapping mode via a register bit setting in the voltage drop mode register 250 or other mode signaling mechanism. In this example, the control circuitry 246 sends control information 248 to the multiplexer circuit 202 to select a reference power tap point input VDD corresponding to the power voltage of the oscillator circuit in sequential combination with corresponding each of a plurality of ground tap point inputs AVSS₁₋ₙ from the on-chip power conductor network and takes a frequency based measurement of each selected set of tap points. Similarly, the control circuitry 246 sends control information 248 that selects the reference ground tap point VSS input corresponding to the ground voltage of the oscillator circuit in sequential combination with each of a plurality of corresponding power tap point inputs VRA₁₋ₙ from the on-chip power conductor network.

For example, in this example, Fₒᵤₜ=Ring Vco Frequency Output. As shown in block 400, a calibration operation is carried out. The control circuitry 246 calibrates the ring oscillator and determines a known voltage to frequency translation. The mux selections are set to the “oscillator reference” power supply and ground voltages (VDD and VSS) of the ring oscillator and the frequency is recorded F_{VDD} as calibration data 247. The oscillator reference power voltage VDD and oscillator reference ground voltage VSS for the ring oscillator are different from those in the power grid being measured and in one implementation are not supplied by the power grid being measured. In one example VDD and VSS are supplied by a different power grid or voltage regulator. The mux selections are then set to a calibration reference voltage and oscillator reference ground voltage (VDD-10 mV and VSS) and the frequency is recorded F_{VDD-10mv} as calibration data 247. For example, the calibration data 247 is stored in memory 244 in one or more latches, registers or other structure. The frequency difference of F_{VDD} minus F_{VDD-10mv} is a result of the 10 mV difference in VDD. Therefore, a frequency to voltage translation can be determined:

$$\frac{V}{Hz} = \frac{10 mV}{{F}_{VDD} - {F}_{VDD - 10 mV}}$$

As shown in block 402 the method includes selecting tap points (VRA1, VSS) and the data 247 representing corresponding F_{VRA1} is recorded in memory 244. For example, the DAC converts the frequency to one or more digital words that are stored in memory, such as in a latch array, SRAM or other suitable memory 244. As shown in block 404, this is repeated for (VRA2, VSS) and as shown in block 406 this process is repeated through selecting VRAn, resulting in F_{VRA1} through F_{VRAn} frequency measurements. VSS is selected for the ground mux on all VRA measurements to keep a static ground reference. As shown in block 408, reference power tap point VDD is selected on the power mux 212, and AVSS1 is selected on the ground mux 210, and F_{AVSS1} is recorded. As shown in blocks 410 and 412, this is repeated for AVSS2 through AVSSn, resulting in F_{AVSS1} through F_{AVSSn} frequency measurements. VDD is selected for the power mux 212 on all AVSS measurements to keep a static power reference.

As shown in block 414, a voltage map is generated. In one example, the recorded F_{VRA1 . . . n} and F_{AVSS1 . . . n} frequencies (e.g., data word values) are used to generate a voltage drop map by the voltage drop map data analyzer 256 of the power grid. In one implementation, a VRA IR drop map is generated by comparing all F_{VRA1 . . . n} to F_{VDD} and translating V/Hz using the known calibrated value:

$$VRA tap point IR drop = ( {F}_{VDD} - {F}_{VRAn} ) * \frac{V}{Hz}$$

The same thing is done to generate the AVSS IR drop map:

$$AVSS tap point IR drop = ( {F}_{VDD} - {F}_{AVSSn} ) * \frac{V}{Hz}$$

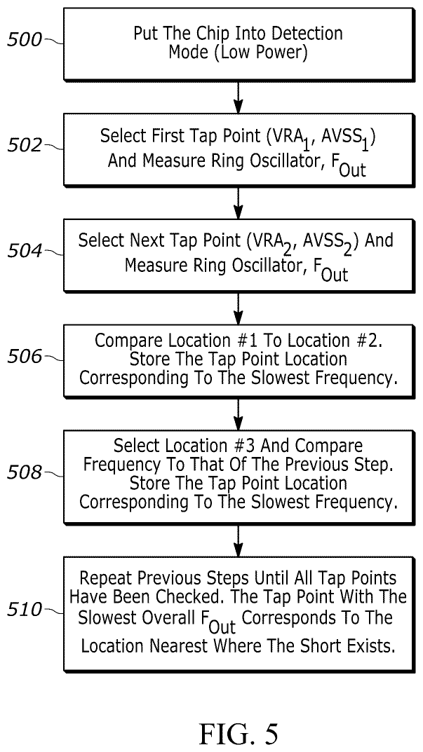

FIG. 5 is a flow chart illustrating an example of a method for detecting a short circuit on the power grid when the voltage drop detection circuitry 106 is set in a short circuit detection mode. For example, the multiplexer circuit includes a plurality of tap point inputs coupled to each of the plurality of power voltage tap points (VRA1-n) on the on-chip conductor network and a plurality of corresponding ground tap point inputs coupled to each of corresponding ground tap points (AVSS1-n) on the on-chip conductor network. The control circuitry 246 send control information 248 to control the multiplexer circuit 202 to output a selected corresponding power tap point and ground tap point pair, such as (VRA1, AVSS1), (VRA2, AVSS2) and so on. The ring oscillator 204 produces a frequency (Fout) corresponding to the selected power voltage tap point and ground tap point pair from the multiplexer circuit that is output on outputs 214 and 216. In this example, the control circuitry 246 provides control information 248 to the multiplexer circuit to select different power voltage tap point and ground tap point pairs.

For example, as shown in block 500 the method includes placing the chip (e.g., the processors and other on-chip circuits) into low power mode, such as by any suitable mechanism as known in the art, such as by a quiescing circuit. The low power mode is a reduced current state which is used to measure a higher resistance short. As shown in blocks 502-510, to measure the voltage (IR), drop of a circuit for a possible short, a similar approach is taken as done by the voltage mapping mode in FIG. 4. The main difference is selecting the power and ground that reference the same corresponding tap points. For instance, VRA1 and AVSS1 are chosen as a tap point pair. This ensures that the power and ground are focused at the designated tap point location (node).

Once the frequency is stored for all tap point pairs the slowest frequency relates to the short location. In another implementation, the control circuitry only measures a subset of tap point pairs utilizing a radix search. This radix search selects a node, measuring the frequency, and following the gradient of nodes down to the lowest value where the short resides. This reduces the number of overall measurements that need to be taken.

For example, as show in block 502 the method includes controlling the multiplexer circuit to output a selected corresponding power voltage tap point VRA1 and ground tap point AVSS1 pair to the ring oscillator and measuring the ring oscillator frequency Fout. For example, the DAC converts the frequency to a digital value and the value is temporarily stored (e.g. latched). It's showing black 504, the message includes selecting a next tab point, such as (VRA2, AVSS2) and measures the ring oscillator frequency Fout. For example, the DAC converts the frequency to a digital value and the value is temporarily stored. As shown in block 506 the method includes comparing location #1 to location #2. For example, the value from (VRA1, AVSS) is compared by a comparator circuit to the value from (VRA2, AVSS2) and the tap point location with the slowest frequency (e.g., lowest value) is stored in memory 244. As shown in block 508, the next location tap point pair, (VRA3, AVSS3) is compared to the previous stored value and the location with the lowest frequency is stored. As shown in block 510 the process is repeated for all tap point pairs and the location corresponding to the slowest overall frequency is determined to be the location nearest to where the short exists and data representing that location is output as the short detection data 253 (see FIG. 2). Hence the control circuitry detects a short circuit in the on-chip power conductor network based on the data representing the frequency corresponding to each selected corresponding power voltage tap point and ground tap point pair.

In one example, the control circuitry stores a minimum threshold for short detection that is preset or programmed. The control circuitry includes one or more counters that represents the measured frequency of the ring oscillator and compares the measured frequency to the threshold and when the measured frequency is less than the threshold, a short condition is detected. For example, if the minimum threshold=5 Ghz and the measured value=4.8 Ghz, then a short has been detected for that tap point and the value and location of the tap point is output over a bus or stored for access by a technician or in system process.

As described above, in a first mode, the control circuitry controls selecting of a first input of the multiplexer circuit corresponding to a power voltage of a ring oscillator and select in sequential combination, each of the plurality of tap points corresponding to ground tap inputs from the on-chip power conductor network and controls selecting of a second input corresponding to a ground voltage of the ring oscillator and select in sequential combination, each of a plurality tap points corresponding to power voltage tap inputs from the on-chip power conductor network to facilitate voltage drop mapping of the power grid. In in a second mode, the control circuitry controls the multiplexer circuit to output a selected corresponding power voltage tap point and ground tap point pair, from the plurality of tap points, on first and second outputs of the multiplexer circuit to facilitate short circuit detection.

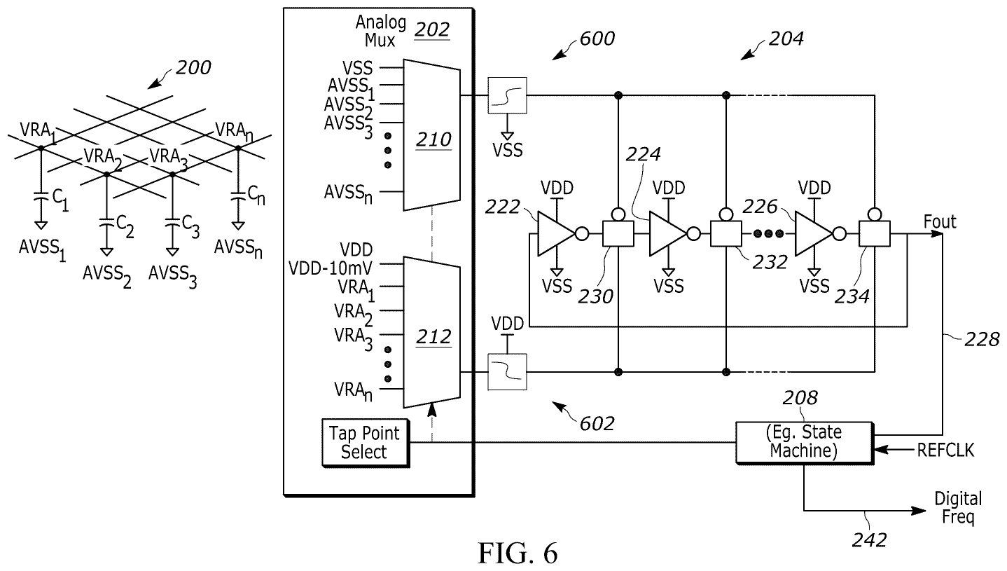

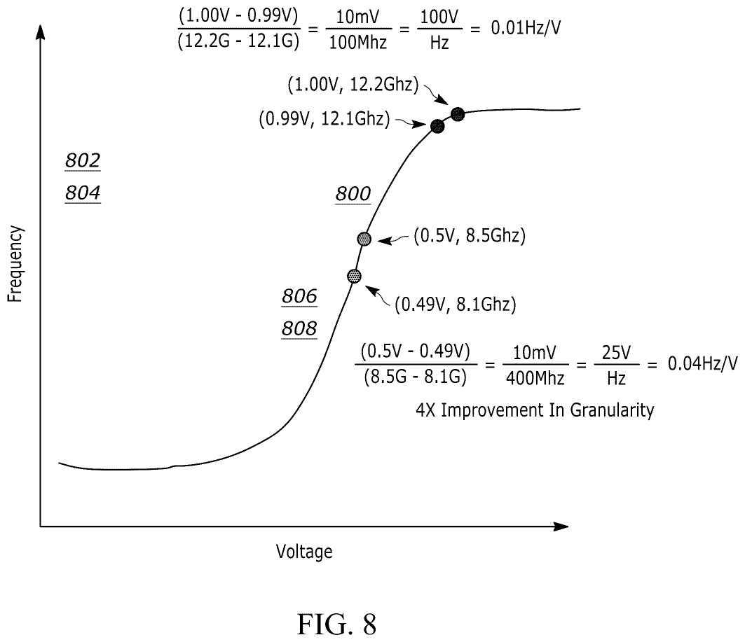

FIG. 6 illustrates another example of voltage drop detection circuitry that has an enhanced voltage/frequency granularity and includes level shifting stages 600 and 602 that level shift the passgate voltages to a higher gain portion of the ring oscillator curve shown in FIG. 8. For example, as shown in FIG. 8 a typical ring VCO frequency curve 800 consists of passgate voltage on the X-axis and Fout frequency on the Y-axis. As voltage increases, the passgates turn more “on” and frequency increases. At higher voltages the passgate goes into saturation and the frequency gain decreases.

In one example, as shown in FIG. 7, the passgates shown in FIG. 2 are a PFET/NFET pair 700 and 702 where the positive terminal connects to the NFET gate and the negative terminal to the PFET gate. The VRA multiplexer output is connected to the positive passgate terminal of the ring oscillator, and the AVSS multiplexer output is connected to the negative terminal.

The voltage drop map data analyzer 256 produces data indicating that a voltage drop beyond a desired threshold has been measured. In this example, a voltage drop threshold is stored in the memory 244 used as a voltage drop data store that is preset or programmed. The voltage drop threshold is compared to a signal representing a measured frequency for a tap point and reference tap point from the multiplexer circuit. In this example, when the measured signal is below the threshold, the voltage drop map data analyzer 256 stores the measured value in memory 244 with data identifying the tap point. This is repeated for each tap point and the stored values form the IR map.

Referring to FIG. 8, when measuring IR drop on a power grid the tap point voltages are near rail and thus in a lower gain region of the ring VCO. As a result, it is harder to differentiate small voltage changes between tap points. This can be rectified by level shifting the tap point voltage to be more centered in the ring VCO frequency curve. The points 802 and 804 represent VRA tap points that are 10 mV apart; resulting in a 100 MHz frequency delta and a gain of 0.01 Hz/V. The points 806 and 808 are obtained by level shifting the points 802 and 804 down by 0.5V and are now centered in the highest gain portion of the ring VCO. A 4× change in frequency occurs with the same 10 mV voltage difference; resulting in 4× gain or 0.04 Hz/V. The improvement in gain helps to differentiate small changes in voltage when determining IR drop across a power grid.

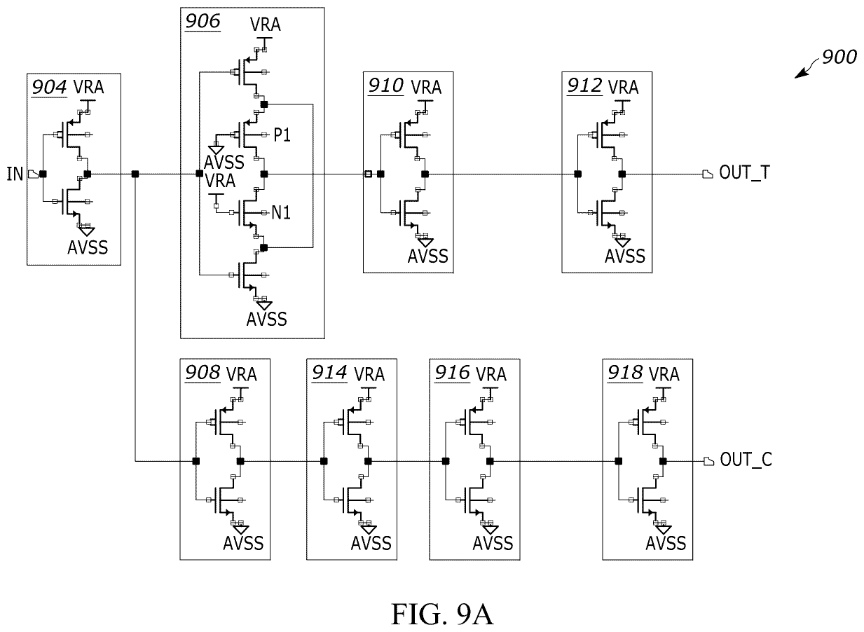

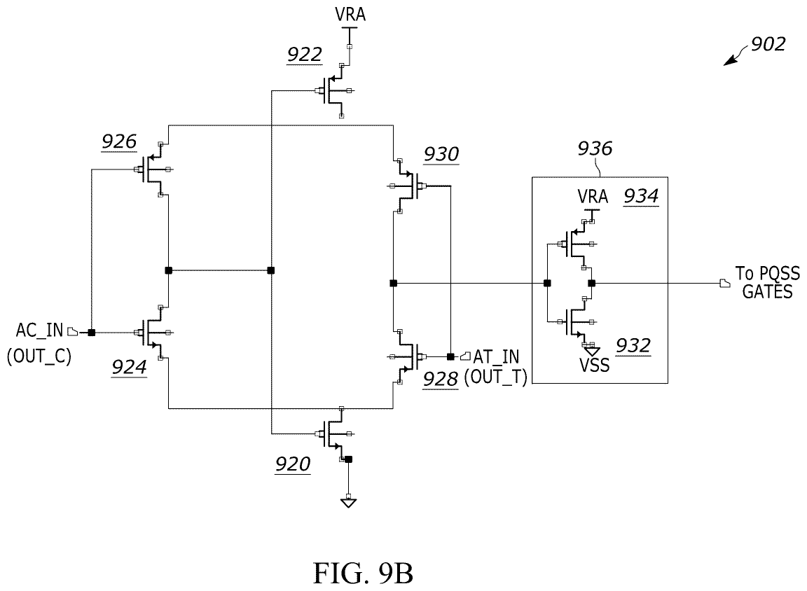

FIGS. 9A and 9B illustrate an example level shifting stage 600 for the ring oscillator, however, any suitable level shifting circuit may be employed. In this example, as shown in FIG. 9A, a splitter circuit 900 makes the signal from the multiplexer 210 differential. The level shifting circuit 902 in FIG. 9B receives the differential output signals from the splitter circuit 900 and uses a source follower NFET configuration and a current source. The current source is varied to center the level shifting voltage at the maximum gain portion of the ring Vco frequency curve. The level shifting circuits may also be enabled independently on power and ground. This allows centering/level shifting of VRA and AVSS tap points independently to better measure their IR drop contribution.

For example, as shown in FIG. 9A, an example splitter circuit 900 receives an input IN that drives inverter 904 whose output is node CLKINOLD which is the input to inverters 906 and 908. The transistors P1 and N1 in 906 slow down the delay of inverter 906 so that the combined inverting delay of three inverters 906, 910 and 912 are equal to the combined delay of the four inverters 908, 914, 916 and 918. The result at output nodes OUT_T and OUT_C is two electrical signals that are 180 degrees out of phase; or stated another way signals OUT_T and OUT_C are differential. Signals OUT_T and OUT_C are inverted 180 degrees from each other. It will be recognized that any other suitable circuit can be employed.

As shown in FIG. 9B, an example level shifter circuit 902 includes transistors that are connected as shown. For example, PMOS transistor 922 and NMOS transistor 920 are coupled to form a complementary current source for the complementary differential pair formed by PMOS transistors 926 and 930 and NMOS transistors 924 and 928. The complementary current source (transistors 922/920) is self-biased by the drains of transistors 926/924 at node zcb_in. When ac_in (OUT_T) goes high, zcb_in goes low turning off transistor 920 and turning on 922 which pushes node zepre higher harder, and output ZT low. When ac_in (OUT_T) goes low, zcb_in goes high turning on 920 and turning off 922 which pushes node zcpre low harder, and output ZT high. The splitter circuit 900 drives ac_in (OUT_T) low and at_in (OUT_C) high and ac_in high and at_in low differentially. Transistors 934 and 932 form an inverter 936 which also functions as an output buffer so the total circuit can drive additional capacitance. It will be recognized that any other suitable circuit can be employed.

As set forth above, in some implementations, the disclosed circuitry is designed to detect voltage drops in a processor chip, such as artificial intelligence (AI) processors used in a hybrid-cloud or in any suitable configuration. In certain implementations, the circuit is configured to run in one or more modes including in a voltage drop mapping mode that maps voltage drops over the power grid of the chip, and/or it can be used in a short circuit detection mode to determine the location of a short circuit within the power grid of the chip. The voltage (IR) drop mapping mode is used to determine power voltage tap points of the power grid (VRA) versus ground tap points of the power grid (AVSS) contributions by measuring all VRA tap points against a reference ground voltage (VSS) in the ring oscillator and by measuring ground tap points (AVSS) in the power grid against a reference supply voltage (VDD) of the ring oscillator.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An integrated circuit comprising:
at least one on-chip power conductor network configured to distribute electrical power to a plurality of electrical components on the integrated circuit; and
voltage drop detection circuitry, operative to select each of a plurality of tap points from the on-chip power conductor network and in response to a plurality of selected tap points, provide data representing a frequency corresponding to a voltage level of each of the plurality of selected tap points.

2. The integrated circuit of claim 1 wherein the voltage drop detection circuitry comprises:
a multiplexer circuit comprising a first output and a second output, each output providing a respective signal from a different selected tap point from the plurality of tap points; and
a ring oscillator comprising an odd number of serially coupled inverters and at least one passgate interposed between each respective serially coupled inverter, each passgate operatively coupled to receive the respective signals from the first and second outputs from the multiplexer circuit.

3. The integrated circuit of claim 2 wherein the multiplexer circuit further comprises a first reference tap point input coupled to a power voltage of the ring oscillator and a second reference tap point input coupled a ground voltage of the ring oscillator and wherein the ring oscillator is operatively coupled to produce a frequency corresponding to the respective signals from the first and second outputs; and
control circuitry operative to provide control information to the multiplexer circuit to:
select the first reference tap point input corresponding to the power voltage of the oscillator circuit in sequential combination with corresponding each of a plurality of ground tap point inputs from the on-chip power conductor network; and
select the second reference tap point input corresponding to the ground voltage of the oscillator circuit in sequential combination with each of a plurality of corresponding power voltage tap point inputs from the on-chip power conductor network.

4. The integrated circuit of claim 2 wherein the multiplexer circuit comprises a plurality of tap point inputs operatively coupled to each of a plurality of power voltage tap points on the on-chip conductor network and a plurality of corresponding ground tap point inputs coupled to each of corresponding ground tap points on the on-chip conductor network, and configured to output a voltage corresponding to a selected corresponding voltage tap point and ground tap point pair;
the ring oscillator operative to produce a frequency corresponding to the voltage corresponding to the selected voltage tap point and ground tap point pair from the multiplexer circuit; and
control circuitry operative to provide control information to the multiplexer circuit to select different voltage tap point and ground tap point pairs.

5. The integrated circuit of claim 3 comprising memory and wherein the control circuitry is operative to store the data representing the frequency corresponding to the respective signals from the first and second outputs from the multiplexer circuit.

6. The integrated circuit of claim 4 wherein the control circuitry is operative, to detect a short circuit in the on-chip power conductor network based on the data representing the frequency.

7. The integrated circuit of claim 4 wherein the multiplexer circuit comprises a ground multiplexer that outputs a first signal from a selected ground tap point, and a voltage multiplexer that outputs a second signal from a selected voltage tap point and further comprising a level shifting circuit operatively coupled to the outputs of each multiplexer.

8. An apparatus comprising:
at least one integrated circuit chip comprising at least one on-chip power conductor network configured to distribute electrical power to a plurality of processors;
a multiplexer circuit, comprising a plurality of tap point inputs from the on-chip power conductor network, a first reference input coupled to a power voltage of a ring oscillator and a second reference input coupled a ground voltage of the ring oscillator and further comprising a first output and a second output, each output providing a respective signal from a different selected tap point from the plurality of tap point inputs; and
the ring oscillator operatively coupled to produce a frequency based on the respective signals received from the first and second outputs; and
control circuitry operative to control the multiplexer circuit to:
in a first mode, select the first input corresponding to the power voltage of the oscillator circuit and select in sequential combination, each of a plurality of tap point inputs corresponding to ground tap inputs from the on-chip power conductor network; and
select the second input corresponding to the ground voltage of the oscillator circuit and select in sequential combination, each of a plurality tap points corresponding to power voltage tap inputs from the on-chip power conductor network; and
in a second mode, the control circuitry is operative to control the multiplexer circuit to output respective signals corresponding to a selected corresponding power voltage tap and ground tap pair, from the plurality of tap points, on the first and second outputs.

9. The apparatus of claim 8 wherein the ring oscillator comprises:
an odd number of serially coupled inverters and at least one passgate interposed between each respective inverter, each passgate operatively coupled to receive respective signals from the first and second outputs from the multiplexer circuit.

10. The apparatus of claim 9 comprising memory and wherein the control circuitry is operative to store data representing the frequency corresponding to the respective signals from the first and second outputs.

11. The apparatus of claim 8 wherein the control circuitry is operative to, detect a short circuit in the on-chip power conductor network based on data representing the frequency.

12. The apparatus of claim 8 wherein the multiplexer circuit comprises a ground multiplexer that outputs a first signal from a selected ground tap point as the second output and a power voltage multiplexer that outputs a second signal from a selected power voltage tap point as the first output and further comprising a level shifting circuit operatively coupled to the first output and a level shifting circuit coupled to the second output.

13. The apparatus of claim 8 comprising a mode register comprising data indicating whether the first mode or the second mode has been selected.

14. A method for detecting voltage drops in an on-chip power conductor network comprising:
selecting, by a multiplexing circuit, each of a plurality of tap points from the on-chip power conductor network; and
in response to a plurality of selected tap points, produce data representing a frequency corresponding to a voltage level of each of the plurality of selected tap points.

15. The method of claim 14 comprising providing control information to select a first input of the multiplexer circuit corresponding to a power voltage of a ring oscillator in sequential combination with each of a plurality of corresponding ground tap inputs from the on-chip power conductor network;
select a second input corresponding to the ground voltage of the ring oscillator in sequential combination with each of a plurality of corresponding voltage tap inputs on-chip power conductor network; and
generating a voltage map of the on-chip power conductor network based on resulting data from the ring oscillator.

16. The method of claim 14 comprising:
controlling a multiplexer circuit comprising a plurality of voltage tap inputs operatively coupled to each of a plurality of power voltage tap points on the on-chip conductor network and a plurality of corresponding ground tap inputs coupled to each of corresponding ground tap points on the on-chip conductor network, to output a voltage corresponding to a selected corresponding power voltage tap point and ground tap point pair; and
detecting a short circuit in the on-chip power conductor network based on the data representing the frequency corresponding to the voltage corresponding to ach selected corresponding power voltage tap point and ground tap point pair.

17. The method of claim 14 comprising:
in a first mode, selecting a first input of the multiplexer circuit corresponding to a power voltage of a ring oscillator and select in sequential combination, each of the plurality of tap points corresponding to ground tap inputs from the on-chip power conductor network;
and selecting a second input corresponding to a ground voltage of the ring oscillator and select in sequential combination, each of a plurality tap points corresponding to power voltage tap inputs from the on-chip power conductor network; and
in a second mode controlling the multiplexer circuit to output respective signals corresponding to a selected corresponding power voltage tap point and ground tap point pair, from the plurality of tap points, on first and second outputs of the multiplexer circuit.

18. The method of claim 17 comprising controlling a ground multiplexer that outputs a selected ground tap point or a ground voltage of a ring oscillator as the second output and controlling a power voltage multiplexer that outputs a selected power voltage tap point or a power voltage of the ring oscillator as the first output.

19. The method of claim 17 comprising level shifting each of the first and second outputs.

20. The method of claim 15 wherein generating the voltage map comprises comparing the resulting data from the ring oscillator to a threshold and when a value is beyond the threshold, storing the data as a value in a voltage map.
